(19) United States
(12) Patent Application Publication
(10) Pub. No.: US 2026/0206332 A1
(43) Pub. Date: Jul. 16, 2026

(54) METHOD AND APPARATUS FOR MANUFACTURING PHOTOVOLTAIC MODULE

(71) Applicant: JIANGSU HYPERION PHOTOVOLTAIC TECHNOLOGY CO., LTD., Yancheng City (CN)

(72) Inventors: Du Jianghai, Yancheng City (CN); Shen Zhimin, Yancheng City (CN); Hao Bin, Yancheng City (CN); Huang Long, Yancheng City (CN); Ma Naihang, Yancheng City (CN); Li Zhixiang, Yancheng City (CN); Yang Yang, Yancheng City (CN); Tao Longzhong, Yancheng City (CN)

(73) Assignee: JIANGSU HYPERION PHOTOVOLTAIC TECHNOLOGY CO., LTD., Yancheng City (CN)

(21) Appl. No.: 19/409,181

(22) Filed: Dec. 4, 2025

(30) Foreign Application Priority Data
Jan. 15, 2025 (CN) 202510060463.5

(51) Int. Cl. H10F 19/80; H10F 10/16; H10F 71/00

(52) U.S. Cl. CPC H10F 19/807; H10F 71/128; H10F 71/137; H10F 10/16

(57) ABSTRACT

Disclosed are a method and an apparatus for manufacturing a photovoltaic module. The method for manufacturing a photovoltaic module includes: heating a glass to a preset temperature; and applying an encapsulation adhesive film on the glass heated to the preset temperature. According to the method for manufacturing a photovoltaic module of the present disclosure, the glass is heated to allow the encapsulation adhesive film to be preliminarily pre-crosslinked and effectively bonded to the glass, which can effectively prevent displacement of the adhesive film from the application position in the subsequent production process, and effectively guarantee a precise distance between the adhesive film and the sealant.

### CROSS-REFERENCE TO RELATED APPLICATIONS

The present application is based on and claims priority from Chinese patent application No. 202510060463.5 filed on Jan. 15, 2025, the entire disclosure of which is incorporated herein by reference.

### TECHNICAL FIELD

The present disclosure relates to the technical field of solar cells, and particularly relates to a method and an apparatus for manufacturing a photovoltaic module.

### BACKGROUND

With the development of the technology in the field of solar cells, the requirement of a photovoltaic module on the sealing performance of cells is higher and higher. Especially for an HJT cell which is extremely sensitive to moisture, poor encapsulation may cause problems like aging of the module and severe power attenuation, making it difficult to guarantee the normal service life.

The HJT encapsulation schemes of the related art typically use a sealant for sealing, where the sealant is applied to an inner periphery of the glass in the photovoltaic module, and then laminated to encapsulate the photovoltaic module together. However, in the process of applying the sealant, the application precision of front and back encapsulation adhesive films, especially a distance between each encapsulation adhesive film and the sealant, is very strictly controlled, otherwise the sealing performance of the module may be affected, thereby seriously affecting the reliability of the module.

### SUMMARY OF THE INVENTION

An embodiment of the present disclosure provides a method for manufacturing a photovoltaic module, including: heating a glass to a preset temperature; and applying an encapsulation adhesive film on the glass heated to the preset temperature.

In some embodiments, the glass is a front glass of the photovoltaic module, and the encapsulation adhesive film is a front encapsulation adhesive film of the photovoltaic module; and/or the glass is a back glass of the photovoltaic module, and the encapsulation adhesive film is a back encapsulation adhesive film of the photovoltaic module.

In some embodiments, the glass is heated to a preset temperature of 50° C. to 70° C.

In some embodiments, the glass is heated to the preset temperature by any one of lamp tube heating, hot blast heating or soleplate heating.

In some embodiments, the glass includes a front glass and a back glass, and the encapsulation adhesive film includes a front encapsulation adhesive film and a back encapsulation adhesive film; and the method for manufacturing a photovoltaic module further includes: assembling the front glass with the front encapsulation adhesive film and the back glass with the back encapsulation adhesive film.

In some embodiments, the method for manufacturing a photovoltaic module includes: finely cutting the front encapsulation adhesive film; heating the front glass to the preset temperature, and then applying the front encapsulation adhesive film on a light-emitting side surface of the front glass; placing cell strings on the front encapsulation adhesive film to form a circuit; arranging a sealant on a periphery of the light-emitting side surface of the front glass; finely cutting the back encapsulation adhesive film; heating the back glass to the preset temperature, and applying the back encapsulation adhesive film on the back glass; and placing the back glass with the back encapsulation adhesive film on the cell strings, and then performing edge sealing and lamination.

In some embodiments, the glass includes a front glass and a back glass, and the encapsulation adhesive film includes a front encapsulation adhesive film and a back encapsulation adhesive film; and the method for manufacturing a photovoltaic module further includes: finely cutting the front encapsulation adhesive film; heating the front glass to the preset temperature, and then applying the front encapsulation adhesive film on a light-emitting side surface of the front glass; placing cell strings on the front encapsulation adhesive film to form a circuit; arranging a sealant on a periphery of the light-emitting side surface of the front glass; finely cutting the back encapsulation adhesive film, and then applying the back encapsulation adhesive film on the cell strings; and placing the back glass on the back encapsulation adhesive film, and then performing edge sealing and lamination.

In some embodiments, the method for manufacturing a photovoltaic module further includes: when the front encapsulation adhesive film is applied on the front glass, an infrared positioning device is used to check and correct an application position of the front encapsulation adhesive film; and/or when the back encapsulation adhesive film is applied on the back glass, an infrared positioning device is used to check and correct an application position of the back encapsulation adhesive film.

The present disclosure provides an apparatus for manufacturing a photovoltaic module, including a heater configured to heat glass to a preset temperature, wherein the glass is a front glass or a back glass of the photovoltaic module.

In the apparatus for manufacturing a photovoltaic module of the present disclosure, the heater is any one of a heating tube, a heat blower or a heating soleplate.

In the apparatus for manufacturing a photovoltaic module of the present disclosure, the apparatus further includes an adhesive film fine-cutting machine and an infrared positioning device disposed above the adhesive film fine-cutting machine, wherein the adhesive film fine-cutting machine is configured to finely cut an encapsulation adhesive film, and the infrared positioning device is configured to check and correct an application position of the encapsulation adhesive film.

According to the method for manufacturing a photovoltaic module of the present disclosure, the glass is heated to allow the encapsulation adhesive film to be preliminarily pre-crosslinked and effectively bonded to the glass, which can effectively prevent displacement of the adhesive film from the application position in the subsequent production process, and effectively guarantee a precise distance between the adhesive film and the sealant.

### BRIEF DESCRIPTION OF THE DRAWINGS

FIG. 1 is a flowchart of a method for manufacturing a photovoltaic module according to some embodiments of the present disclosure.

FIG. 2 is a flowchart of a method for manufacturing a photovoltaic module according to some other embodiments of the present disclosure.

FIG. 3 is a flowchart of a method for manufacturing a photovoltaic module according to still other embodiments of the present disclosure.

FIG. 4 is a structural diagram of a photovoltaic module according to some embodiments of the present disclosure.

FIG. 5 is a schematic diagram of heating glass in a method for manufacturing a photovoltaic module according to some embodiments of the present disclosure.

FIG. 6 is a schematic diagram of infrared positioning and correction in a method for manufacturing a photovoltaic module according to some embodiments of the present disclosure.

### LIST OF REFERENCE SIGNS

1—front glass; 2—front encapsulation adhesive film; 3—cell string; 4—back encapsulation adhesive film; and 5—back glass.

### DETAIL DESCRIPTION OF THE EMBODIMENTS

To improve understanding of the technical solution of the present disclosure for those skilled in the art, the technical solution of the present disclosure will be described below in detail in conjunction with the accompanying drawings.

Exemplary embodiments will be described more sufficiently below with reference to the accompanying drawings, but which may be embodied in different forms and should not be construed as limited to the embodiments set forth herein. Rather, these embodiments are provided so that the present disclosure will be thorough and complete, and will fully convey the scope of the present disclosure to those skilled in the art.

The embodiments of the present disclosure and features thereof may be combined with each other as long as they are not contradictory.

As used herein, the term “and/or” includes any and all combinations of one or more of the associated listed items.

The terminology used herein is for the purpose of describing specific embodiments only and is not intended to limit the present disclosure. As used herein, the singular forms “a” “an” and “the” are intended to include the plural forms as well, unless the context clearly indicates otherwise. It will be further understood that as used herein, the terms “comprise” and/or “consist of . . . ” specify the presence of the stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the existing art and the present disclosure, and will not be interpreted in an idealized or overly formal sense unless expressly so defined herein.

In the HJT encapsulation scheme of the related art, if the distance between an edge of an adhesive film and the sealant is too large, a large number of bubbles may be generated between the sealant and the adhesive film after lamination, which may seriously affect the reliability of the module; and if the distance between the edge of the adhesive film and the sealant is too small, and there is no sufficient flowing space between the adhesive film and the sealant during the lamination process, the adhesive film may be extruded to the position of the sealant, and form adhesive film piercing in the sealant, which may lead to an insufficient actual width of the sealant and seriously affect the sealing performance of the module. Moreover, after the adhesive film is applied, the adhesive film may be easily shifted due to various factors, such as jittering of a production line, air blowing from a production line air conditioner, manual repair, friction in a glass combining process and the like, leading to a changed distance between the adhesive film and the sealant, and further affecting the reliability of the laminated HJT module.

In view of this, an embodiment of the present disclosure provides a method for manufacturing a photovoltaic module, which, as shown in FIG. 1, includes:
S1—heating a glass to a preset temperature; and
S2—applying an encapsulation adhesive film on the glass heated to the preset temperature.

In some embodiments, the glass is a front glass of the photovoltaic module, and the encapsulation adhesive film is a front encapsulation adhesive film of the photovoltaic module; and/or the glass is a back glass of the photovoltaic module, and the encapsulation adhesive film is a back encapsulation adhesive film of the photovoltaic module.

In some embodiments, the glass is heated to a preset temperature of 50° C. to 70° C.

In some embodiments, the glass is heated to the preset temperature by any one of lamp tube heating, hot blast heating or soleplate heating.

In some embodiments, the glass includes a front glass and a back glass, and the encapsulation adhesive film includes a front encapsulation adhesive film and a back encapsulation adhesive film; and the method for manufacturing a photovoltaic module further includes: assembling the front glass with the front encapsulation adhesive film and the back glass with the back encapsulation adhesive film.

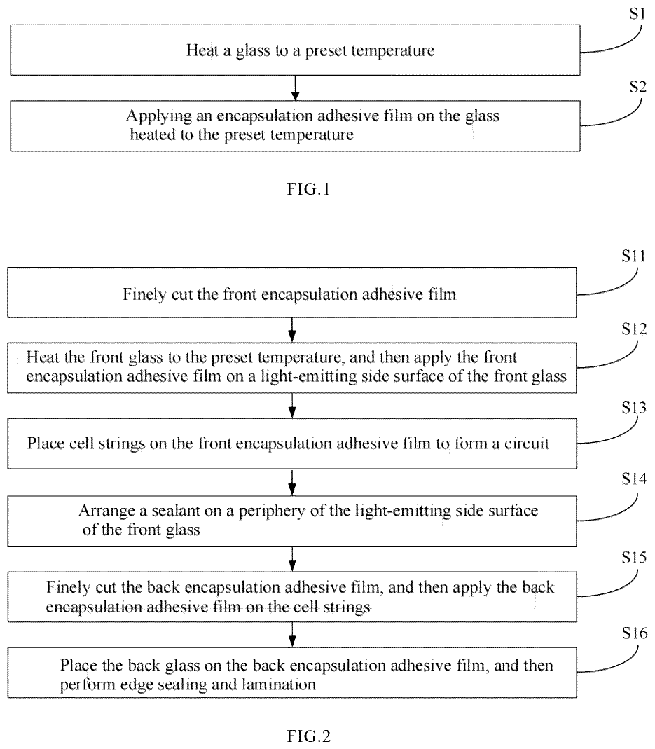

As shown in FIG. 2, a method for manufacturing a photovoltaic module according to some embodiments of the present disclosure includes:
S11—finely cutting the front encapsulation adhesive film;
S12—heating the front glass to the preset temperature, and then applying the front encapsulation adhesive film on a light-emitting side surface of the front glass;
S13—placing cell strings on the front encapsulation adhesive film to form a circuit;
S14—arranging a sealant on a periphery of the light-emitting side surface of the front glass;
S15—finely cutting the back encapsulation adhesive film, and then applying the back encapsulation adhesive film on the cell strings; and
S16—placing the back glass on the back encapsulation adhesive film, and then performing edge sealing and lamination.

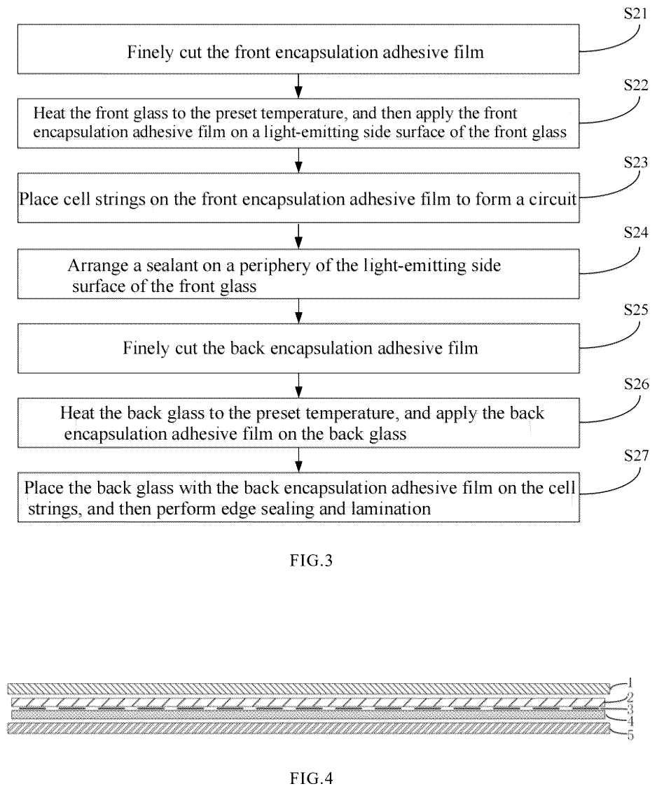

As shown in FIG. 3, a method for manufacturing a photovoltaic module according to some embodiments of the present disclosure includes:
S21—finely cutting the front encapsulation adhesive film;
S22—heating the front glass to the preset temperature, and then applying the front encapsulation adhesive film on a light-emitting side surface of the front glass;
S23—placing cell strings on the front encapsulation adhesive film to form a circuit;
S24—arranging a sealant on a periphery of the light-emitting side surface of the front glass;
S25—finely cutting the back encapsulation adhesive film;
S26—heating the back glass to the preset temperature, and applying the back encapsulation adhesive film on the back glass; and
S27—placing the back glass with the back encapsulation adhesive film on the cell strings, and then performing edge sealing and lamination.

According to the method for manufacturing a photovoltaic module provided in some embodiments of the present disclosure, when the front/back encapsulation adhesive film is applied on a surface of the front/back glass, an infrared positioning device is used to check and correct an application position of the encapsulation adhesive film.

As shown in FIG. 4, the photovoltaic module according to some embodiments of the present disclosure includes a front glass 1, a front encapsulation adhesive film 2, a cell string 3, a back encapsulation adhesive film 4, a back glass 5, and a sealant (not shown).

The encapsulation adhesive film is an ethylene-vinyl acetate copolymer (EVA) adhesive film. At least one of the glasses is a light-transmitting glass which may be made of a fully transparent or translucent material. The cell string may include one or more cell modules electrically connected with each other. The sealant includes, but is not limited to, butyl rubber, butyl tape, and POE, as long as the front and a back glasses can be sealed.

As shown in FIG. 5, the present disclosure further provides an apparatus for manufacturing a photovoltaic module, including a heater for heating the front/back glass.

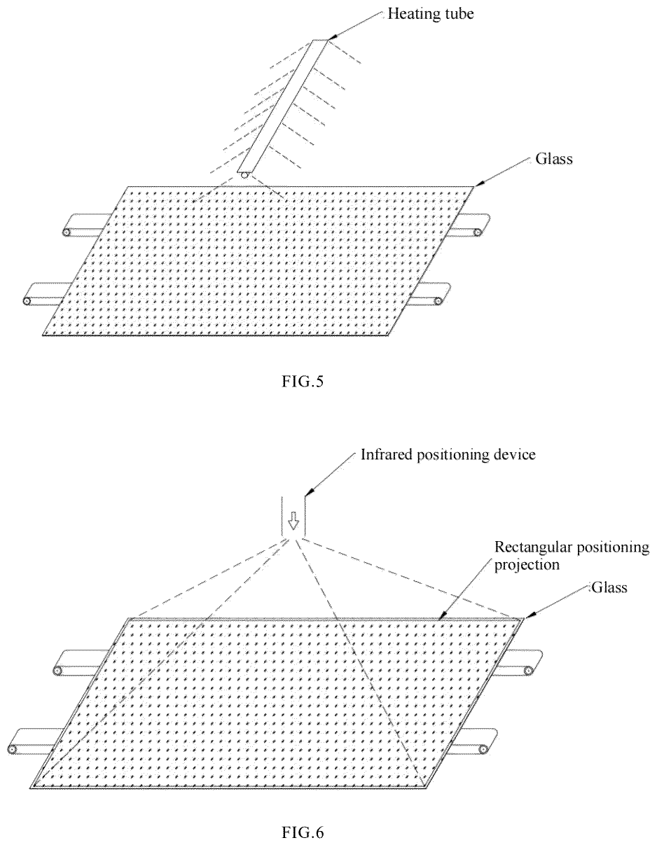

As shown in FIG. 6, the apparatus for manufacturing a photovoltaic module according to some embodiments of the present disclosure further includes an infrared positioning device disposed above an adhesive film fine-cutting machine. The infrared positioning device can project a rectangular positioning projection on the glass, assist in checking whether the application position of the encapsulation adhesive film is accurate, and allow manual correction if the application position is inaccurate.

According to some embodiments of the present disclosure, the method for manufacturing a photovoltaic module includes: cutting the front encapsulation adhesive film by an adhesive film fine-cutting machine to obtain an encapsulation adhesive film of a desired size; heating the front glass to a preset temperature of 50° C. to 70° C. by a heater, and then applying the front encapsulation adhesive film on a light-emitting side surface of the front glass; placing cell strings on the front encapsulation adhesive film by a typesetting machine, and welding the cell strings into a complete circuit by a stack welding machine; arranging a sealant on a periphery of the light-emitting side surface of the front glass by a sealant dispenser, while keeping a proper clearance between the sealant and the encapsulation adhesive film; finely cutting the back encapsulation adhesive film by an adhesive film fine-cutting machine; then applying the back encapsulation adhesive film on the cell strings; and placing the back glass on the back encapsulation adhesive film, and then performing edge sealing and lamination.

According to some other embodiments of the present disclosure, the method for manufacturing a photovoltaic module includes: cutting the front encapsulation adhesive film by an adhesive film fine-cutting machine to obtain an encapsulation adhesive film of a desired size; heating the front glass to a preset temperature of 50° C. to 70° C. by a heater, and then applying the front encapsulation adhesive film on a light-emitting side surface of the front glass; placing cell strings on the front encapsulation adhesive film by a typesetting machine, and welding the cell strings into a complete circuit by a stack welding machine; arranging a sealant on a periphery of the light-emitting side surface of the front glass by a sealant dispenser, while keeping a proper clearance between the sealant and the encapsulation adhesive film; finely cutting the back encapsulation adhesive film by an adhesive film fine-cutting machine; heating the back glass to a preset temperature of 50° C. to 70° C. by a heater, and then applying the back encapsulation adhesive film on an inner side surface of the back glass; and placing the back glass with the back encapsulation adhesive film on the cell strings, and then performing edge sealing and lamination.

By applying the adhesive film on the heated glass to allow the encapsulation adhesive film to be preliminarily pre-crosslinked and effectively bonded to the glass, displacement of the adhesive film from the application position can be effectively prevented in the subsequent production process, and a precise distance between the adhesive film and the sealant can be guaranteed. Further, by pre-bonding the back encapsulation adhesive film and the back glass, the applying process of the back encapsulation adhesive film and the placing process of the back glass are combined into one process, and a distance between the back encapsulation adhesive film and the edge of the sealant is effectively ensured.

According to still other embodiments of the present disclosure, the method for manufacturing a photovoltaic module includes: cutting the front encapsulation adhesive film by an adhesive film fine-cutting machine to obtain an encapsulation adhesive film of a desired size; heating the front glass to a preset temperature of 50° C. to 70° C. by a heater, and then applying the front encapsulation adhesive film on a light-emitting side surface of the front glass; checking whether the application position of the encapsulation adhesive film is accurate by an infrared positioning device disposed above the adhesive film fine-cutting machine, and performing manual correction if the application position is inaccurate; placing cell strings on the front encapsulation adhesive film by a typesetting machine, and welding the cell strings into a complete circuit by a stack welding machine; arranging a sealant on a periphery of the light-emitting side surface of the front glass by a sealant dispenser, while keeping a proper clearance between the sealant and the encapsulation adhesive film; finely cutting the back encapsulation adhesive film by an adhesive film fine-cutting machine; then applying the back encapsulation adhesive film on the cell strings; and placing the back glass on the back encapsulation adhesive film, and then performing edge sealing and lamination.

According to some other embodiments of the present disclosure, the method for manufacturing a photovoltaic module includes: cutting the front encapsulation adhesive film by an adhesive film fine-cutting machine to obtain an encapsulation adhesive film of a desired size; heating the front glass to a preset temperature of 50° C. to 70° C. by a heater, and then applying the front encapsulation adhesive film on a light-emitting side surface of the front glass; checking whether the application position of the encapsulation adhesive film is accurate by an infrared positioning device disposed above the adhesive film fine-cutting machine, and performing manual correction if the application position is inaccurate; placing cell strings on the front encapsulation adhesive film by a typesetting machine, and welding the cell strings into a complete circuit by a stack welding machine; arranging a sealant on a periphery of the light-emitting side surface of the front glass by a sealant dispenser, while keeping a proper clearance between the sealant and the encapsulation adhesive film; finely cutting the back encapsulation adhesive film by an adhesive film fine-cutting machine; heating the back glass to a preset temperature of 50° C. to 70° C. by a heater, and then applying the back encapsulation adhesive film on an inner side surface of the back glass; and placing the back glass with the back encapsulation adhesive film on the cell strings, and then performing edge sealing and lamination.

By setting the parameters of the infrared positioning device, a red box for positioning is projected on the front glass, which has a size the same as the front encapsulation adhesive film, and the projection position is the correct application position of the front encapsulation adhesive film. Therefore, after the front encapsulation adhesive film is applied on the light-emitting side surface of the front glass, an operator can visually determine whether the application position of the adhesive film is accurate and make a correction in time by observing the correspondence between edge lines of the adhesive film and the position of the red box. Meanwhile, since the finely cut encapsulation adhesive film has a size consistent with the red box, if one or two sides of the adhesive film exceed the positioning red box, the other one or two sides of the adhesive film will naturally fall within the box. In this case, the adhesive film exceeding the box range may be cut off by a cutter on the adhesive film fine-cutting machine, and the part of the adhesive film cut off can be just used for supplementing the missing side(s).

To improve understanding of the technical solutions provided in the embodiments of the present disclosure for those skilled in the art, the technical solutions provided in the embodiments of the present disclosure will be further described in detail below with the help of specific embodiments.

### EXAMPLE 1

A process of manufacturing a 66-cell 210 HJT module includes: cutting the front encapsulation adhesive film by an adhesive film fine-cutting machine to obtain an encapsulation adhesive film with a size of 2368 mm×1287 mm; heating the front glass to a preset temperature of 60° C. by a lamp tube heater, and then applying the front encapsulation adhesive film on a light-emitting side surface of the front glass; placing 12 cell strings on the front encapsulation adhesive film by a typesetting machine, and welding the cell strings into a complete circuit by a stack welding machine; arranging black butyl rubber as a sealant on a periphery of the light-emitting side surface of the front glass by a sealant dispenser, while keeping a clearance of 3 mm between the butyl rubber and the encapsulation adhesive film; similarly, obtaining a back side encapsulation adhesive film with the same size as the front side encapsulation adhesive film by an adhesive film fine-cutting machine, and then applying the back encapsulation adhesive film on the cell strings; and placing the back glass on the back encapsulation adhesive film, and then performing edge sealing and lamination.

### EXAMPLE 2

A 66-cell 210 HJT module is manufactured in the same method as in example 1, except that: heating the front glass to a preset temperature of 55° C. by a heater, and then applying the front encapsulation adhesive film on a light-emitting side surface of the front glass; moreover, after finely cutting the back encapsulation adhesive film, firstly, heating the back glass to a preset temperature of 65° C. by a heater, and then applying the back encapsulation adhesive film on an inner side surface of the back glass; and finally, placing the back glass with the back encapsulation adhesive film on the cell strings, and then performing edge sealing and lamination.

### EXAMPLE 3

A 66-cell 210 HJT module is manufactured in the same method as in example 1, except that: heating the front glass to a preset temperature of 65° C. by a heater, and then applying the front encapsulation adhesive film on a light-emitting side surface of the front glass; checking whether the application position of the encapsulation adhesive film is accurate by an infrared positioning device disposed above the adhesive film fine-cutting machine, and perform manual correction if the application position is inaccurate.

### EXAMPLE 4

A 66-cell 210 HJT module is manufactured in the same method as in example 1, except that: heating the front glass to a preset temperature of 70° C. by a heater, and then applying the front encapsulation adhesive film on a light-emitting side surface of the front glass; checking whether the application position of the encapsulation adhesive film is accurate by an infrared positioning device disposed above the adhesive film fine-cutting machine, and performing manual correction if the application position is inaccurate; moreover, after finely cutting the back encapsulation adhesive film, firstly, heating the back glass to a preset temperature of 60° C. by a heater, and then applying the back encapsulation adhesive film on an inner side surface of the back glass; and finally, placing the back glass with the back encapsulation adhesive film on the cell strings, and then performing edge sealing and lamination.

### Comparative Example 1

A 66-cell 210 HJT module is manufactured in the same method as in example 1, except that a front encapsulation adhesive film is directly applied on a light-emitting side of the front glass without heating the front glass.

Performance testing is conducted on the photovoltaic modules obtained in the examples and the comparative example, and a comparison of performance parameters of the photovoltaic modules is shown in the table below.

TABLE 1

| | Whether butyl rubber | |
|---|---|---|
| | piercing is present | Power |
| | on a side surface of | attenuation |
| | the module after | after DH2000 |
| Experimental group | lamination | aging test |
| Example 1 | No | 1.03% |
| Example 2 | No | 1.49% |
| Example 3 | No | 2.48% |
| Example 4 | No | 1.55% |
| Comparative example 1 | Yes | 3.71% |

As can be seen from the results in table 1, according to the method for manufacturing a photovoltaic module of the present disclosure, the application position of the encapsulation adhesive film is more accurate by heating the glass, and the problem of displacement of the encapsulation adhesive film during operation is eliminated, so that a precise distance between the adhesive film and the sealant can be effectively guaranteed, the power attenuation of the photovoltaic module can be reduced, and the reliability of the photovoltaic module can be improved.

The present disclosure has disclosed exemplary embodiments, and although specific terms are employed, they are used and should be interpreted merely in a generic and descriptive sense, not for purposes of limitation. In some instances, as would be apparent to one skilled in the art, features, characteristics and/or elements described in connection with a particular embodiment may be used alone or in combination with features, characteristics and/or elements described in connection with another embodiment, unless expressly stated otherwise. It will, therefore, be understood by those skilled in the art that various changes in form and details may be made therein without departing from the scope of the present disclosure as set forth in the appended claims.

What is claimed is:

1. A method for manufacturing a photovoltaic module, comprising:
heating a glass to a preset temperature; and
applying an encapsulation adhesive film on the glass heated to the preset temperature.

2. The method for manufacturing a photovoltaic module according to claim 1, wherein the glass is a front glass of the photovoltaic module, and the encapsulation adhesive film is a front encapsulation adhesive film of the photovoltaic module; and/or
the glass is a back glass of the photovoltaic module, and the encapsulation adhesive film is a back encapsulation adhesive film of the photovoltaic module.

3. The method for manufacturing a photovoltaic module according to claim 1, wherein the glass is heated to a preset temperature of 50° C. to 70° C.

4. The method for manufacturing a photovoltaic module according to claim 1, wherein the glass is heated to the preset temperature by any one of lamp tube heating, hot blast heating or soleplate heating.

5. The method for manufacturing a photovoltaic module according to claim 2, wherein the glass comprises a front glass and a back glass, and the encapsulation adhesive film comprises a front encapsulation adhesive film and a back encapsulation adhesive film; and the method for manufacturing a photovoltaic module further comprises:
assembling the front glass with the front encapsulation adhesive film and the back glass with the back encapsulation adhesive film.

6. The method for manufacturing a photovoltaic module according to claim 5, wherein the method for manufacturing a photovoltaic module comprises:
finely cutting the front encapsulation adhesive film;
heating the front glass to the preset temperature, and then applying the front encapsulation adhesive film on a light-emitting side surface of the front glass;
placing cell strings on the front encapsulation adhesive film to form a circuit;
arranging a sealant on a periphery of the light-emitting side surface of the front glass;
finely cutting the back encapsulation adhesive film;
heating the back glass to the preset temperature, and applying the back encapsulation adhesive film on the back glass; and
placing the back glass with the back encapsulation adhesive film on the cell strings, and then performing edge sealing and lamination.

7. The method for manufacturing a photovoltaic module according to claim 2, wherein the glass comprises a front glass and a back glass, and the encapsulation adhesive film comprises a front encapsulation adhesive film and a back encapsulation adhesive film; and the method for manufacturing a photovoltaic module further comprises:
finely cutting the front encapsulation adhesive film;
heating the front glass to the preset temperature, and then applying the front encapsulation adhesive film on a light-emitting side surface of the front glass;
placing cell strings on the front encapsulation adhesive film to form a circuit;
arranging a sealant on a periphery of the light-emitting side surface of the front glass;
finely cutting the back encapsulation adhesive film, and then applying the back encapsulation adhesive film on the cell strings; and
placing the back glass on the back encapsulation adhesive film, and then performing edge sealing and lamination.

8. The method for manufacturing a photovoltaic module according to claim 2, wherein the method for manufacturing a photovoltaic module further comprises:
when the front encapsulation adhesive film is applied on the front glass, an infrared positioning device is used to check and correct an application position of the front encapsulation adhesive film; and/or
when the back encapsulation adhesive film is applied on the back glass, an infrared positioning device is used to check and correct an application position of the back encapsulation adhesive film.

9. An apparatus for manufacturing a photovoltaic module, comprising a heater configured to heat glass to a preset temperature, wherein the glass is a front glass or a back glass of the photovoltaic module.

10. The apparatus for manufacturing a photovoltaic module according to claim 9, wherein the heater is any one of a heating tube, a heat blower or a heating soleplate.

11. The apparatus for manufacturing a photovoltaic module according to claim 9, wherein the apparatus further comprises an adhesive film fine-cutting machine and an infrared positioning device disposed above the adhesive film fine-cutting machine, wherein the adhesive film fine-cutting machine is configured to finely cut an encapsulation adhesive film, and the infrared positioning device is configured to check and correct an application position of the encapsulation adhesive film.
